(19) United States
(12) Patent Application Publication
(10) Pub. No.: US 2009/0103263 A1
(43) Pub. Date: Apr. 23, 2009

(54) Hand-held electric power tool with monitoring of motor temperature

(75) Inventors: Michael Fuchs, Bad Woerishofen (DE); Torsten Luettich, Kaufering (DE); Roland Schaer, Grabs (CH); Roland Schwab, Geltendorf (DE); Stefan Kiefersauer, Augsburg (DE)

Correspondence Address: ABELMAN, FRAYNE & SCHWAB, 666 THIRD AVENUE, 10TH FLOOR, NEW YORK, NY, 10017, US

(73) Assignee: Hilti Aktiengesellschaft

(21) Appl. No.: 12/288,122

(22) Filed: Oct. 15, 2008

(30) Foreign Application Priority Data
Oct. 18, 2007 (DE) 10 2007 000 524.7

(51) Int. Cl. H05K 7/20

(52) U.S. Cl. 361/695

(57) ABSTRACT

A hand-held electric power tool has a hand-held outer housing (23), an electric motor (1) with a fan (3) for generating a flow (4) of cooling air, and an electronics module (2) having an electronic motor control (2a) and a computing element (2b) for monitoring the motor temperature and including a motor temperature model (11), and a temperature sensor (5) arranged directly at the electronics module (2) and connected therewith.

### BACKGROUND OF THE INVENTION

1. Field of the Invention

The invention relates to a device for thermal monitoring of an electric motor of a hand-held electric power tool which is operated by the electric motor with an electronic motor control, in particular a hammer drill, a chisel hammer, a diamond drilling tool, a hand-held circular saw, or a disk sander.

2. Description of the Prior Art

According to German Utility Model DE 92 03 945 U, two temperature sensors for measuring the ambient temperature and the temperature at the power switch are arranged on an electronics module for indirect thermal monitoring of an electric motor in a hand-held electric power tool.

According to German Publication DE 38 04 679, the behavior over time of the motor temperature is simulated by a real temperature conducting path in the form of a heatsink of the power switch. However, approximating the motor temperature, particularly the winding temperature, by the temperature at the power switch is too imprecise for high-power (>1000 Watts) hand-held electric power tools.

An arrangement for protecting an electric motor against thermal overloading is described in International Publication WO 93 23904 and DE 42 16 040. During the power-on period of the electric motor, its power loss, or a value proportional to the power loss, is calculated over time based on measured motor data and is integrated, and the integration value is then compared to a threshold value. When the threshold value is reached or exceeded, a motor switch-off signal is generated. In the described arrangements, thermal effects of the thermal economy of the motor, e.g., the effect of the convective cooling by the cooling air and the dissipation of heat to other structural component parts, are essentially not taken into account. Accordingly, a reliable simulation of the thermal behavior of the motor and a sufficient, dependable protection of the motor cannot be achieved.

German Publication DE 199 39 997 describes a safety cutoff which interrupts the energy supply to an electric motor when a corrected temperature signal exceeds a given threshold value. The corrected temperature signal is yielded by calculation depending on a temperature measurement signal which is sensed in the vicinity of a motor winding by a temperature sensor and its past measurement signals. The device described herein serves merely to compensate for the damping characteristic of the heat conduction between the temperature measurement location at the temperature sensor and the relevant temperature at the motor, e.g., at the winding. It is a decisive disadvantage that the measurement must be carried out in the immediate vicinity of the winding, i.e., at the motor.

European Publication EP 1 450 460 describes a device for thermal monitoring of an electric motor at a drive regulating unit which calculates the thermal state of the motor by means of at least one temperature measurement in the vicinity of the electric motor, stored motor parameters, operating parameters of the motor, and a thermal, dynamic model of the motor, and specifies electric operating values such as voltage and current for the motor operation. In the described device, the relevant temperature, e.g., a winding temperature, is calculated by means of a thermal dynamic model. The calculation error is minimized by means of at least one temperature measured directly at the electric motor. It is disadvantageous that measurements must be taken in the immediate vicinity of the winding, i.e., at the motor.

Further, according to German Publication DE 197 05 397, the relevant data for determining the motor temperature is stored in a nonvolatile memory.

### SUMMARY OF THE INVENTION

It is the object of the invention to realize a hand-held electric power tool with a motor temperature monitoring which is constructed modularly so as to be usable for different hand-held electric power tools and can be assembled using simple technology.

This and other objects of the present invention which will become apparent hereinafter, are achieved by providing a hand-held electric power tool having an outer housing that can be held in the hand, an electric motor with a fan for generating a flow of cooling air, and an electronics module which is connected to a temperature sensor and which has an electronic motor control and computing means for monitoring the motor temperature and having a motor temperature model, with the temperature sensor being arranged directly at the electronics module.

Using the temperature sensor, which is arranged directly at the electronics module, the temperature in the electric motor (for example, the winding temperature) can be calculated by the computing means and the motor temperature model without a need to additionally mount and hook up the temperature sensor at an electric motor (which is usually pre-assembled in a modular manner and differs depending on the tool platform). Accordingly, mounting is simplified by doing away with the hook-up step, which is important economically in case of high numbers of units. In addition, any platform-specific peculiarities are eliminated in assembly.

The temperature sensor is advantageously arranged on the inflow side between the outer housing and the electric motor so that the temperature sensor, which is practically (thermally) completely decoupled from the electric motor, measures the cooling air temperature in a reaction-free manner, which substantially simplifies calculation of the temperature in the electric motor.

The computing means advantageously contain a programmed algorithm for monitoring the temperature of the electric motor which, depending on a calculated actual motor temperature, interrupts the motor current of the electric motor via an electronic switch of the motor control when a calculated current limit value is exceeded. This permits making use of the thermal load capacity of the electric motor to a most possible extent.

The motor temperature model is advantageously based on actual measurements of the motor current, the motor voltage, the cooling air temperature of the cooling air flow, and the past motor temperature so that the thermal motor behavior can be calculated in a reaction-free manner from the motor temperature.

The motor temperature model itself advantageously comprises a logical circuit of software modules which depend directly or indirectly on the actual cooling air temperature, the actual motor current, and the actual motor voltage as variables, and on the past motor temperatures as parameters, so that the motor temperature model represents an explicit mapping of the motor temperature.

The computing means advantageously has a programmed storage module which is write-connected to a nonvolatile data memory so that data can be acquired and stored for calculating the cooling behavior.

The computing means is also advantageously connected to the power source after the electric motor is switched off, so that further measurements of the cooling air temperature can be carried out and stored by the storage module over a sufficiently long time period.

A programmed initialization module which is read-connected to the data memory is advantageously provided in the computing means so that the actual motor temperature can be determined based on a cooling function.

The novel features of the present invention, which are considered as characteristic for the invention, are set forth in the appended claims. The invention itself, however, both as to its construction and its mode of operation, together with additional advantages and objects thereof, will be best understood from the following detailed description of preferred embodiments, when read with reference to the accompanying drawings.

### BRIEF DESCRIPTION OF THE DRAWINGS

The drawings show:

FIG. 1 a schematic view of a hand-held electric power tool according to the present invention;

FIG. 2 a scheme illustrating the control algorithm;

FIG. 3 a scheme of a motor temperature model;

FIG. 4 a scheme of a storage module; and

FIG. 5 a scheme of an initialization module.

### DETAILED DESCRIPTION OF THE PREFERRED EMBODIMENT

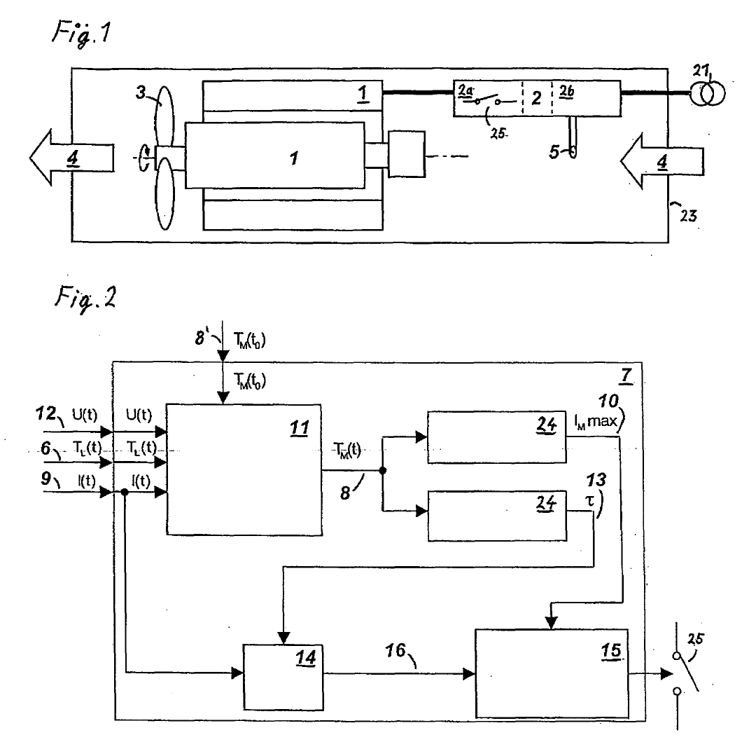

According to FIG. 1, the hand-held electric power tool which is only shown schematically, is driven by an electric motor 1. An electronics module 2 is arranged in the hand-held electric power tool in such a way that a cooling air flow 4 that is aspirated in from the outside by a fan 3 flows over this electronics module 2. The electronics module 2 is arranged on the inflow side, i.e., referring to the direction of flow, in front of the electric motor 1 to be cooled. A temperature sensor 5 is located on the electronics module 2, a cooling air flow 4 flows around this temperature sensor 5 which senses the cooling air temperature 6 (FIG. 2). Accordingly, the temperature sensor 5 is almost completely thermally decoupled from the electric motor 1. The electronics module 2 contains a motor control 2a with an electronic switch 25 and computing means 2b. The computing means 2b and the temperature sensor 5 are also supplied with energy by a power source 21 (network power supply or battery pack) when the electric motor 1 is switched off means of by a conventional energy-saving standby circuit.

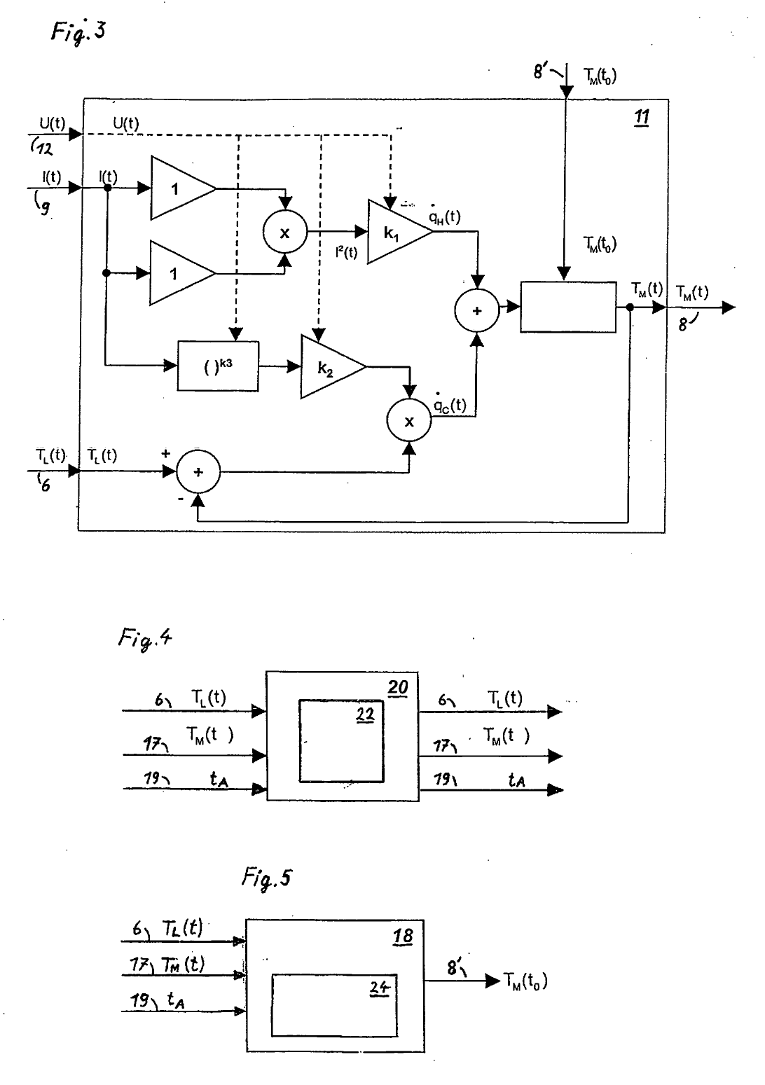

According to FIG. 2, a programmed algorithm 7 for monitoring the motor temperature, which is carried out in the computing means 2b (FIG. 1), safeguards the electric motor (FIG. 1) permanently over time against thermal overloading. The algorithm 7, dependent on a calculated actual motor temperature 8, interrupts the motor current 9 of the electric motor 1 (FIG. 1) by an electronic switch 25 of the motor control 2a (FIG. 1) when a calculated current limiting value 10 is exceeded. To this end, the algorithm 7 accesses a programmed motor temperature model 11 (see also FIG. 3) which simulates the thermal behavior of the motor based on actual measurements of the motor current 9 and the motor voltage 12 of the electric motor 1 (FIG. 1) and the cooling air temperature 6 of the cooling air flow 4 (FIG. 1), and the past motor temperatures 17 and accordingly calculates the actual motor temperature 8 in the form of a winding temperature. Based on this actual motor temperature 8, a time constant 13 for a lowpass filter 14 for filtering the motor current 9 to a lowpass-filtered motor current average 16 and a maximum permissible current limit value 10 are determined by a mapping function 24 in each instance and are compared to one another by a comparator 15. If the lowpass-filtered motor current average 16 exceeds the maximum permissible motor current 10, the comparator 15 emits a signal by which the electric motor 1 (FIG. 1) is switched off. Of course, other motor temperatures 8 such as bearing temperature, plug contact temperature, etc. can also be monitored simultaneously in the electric motor 1 (FIG. 1) by the algorithm 7 in that the algorithm 7 is formed analogously and is cascaded.

According to FIG. 3, the motor temperature model 11 itself comprises a logical circuit of software modules (in the form of amplifiers, adders, multipliers, integrators) each of which depends directly or indirectly on the actual cooling air temperature 6, the actual motor current 9 and the actual motor voltage 12 as variables and on the initial motor temperature 8′ as parameter.

According to FIG. 4, the switch-off time 19, the actual past motor temperatures 17 and the cooling air temperature 6 are stored in a nonvolatile memory by the computing means 2b (FIG. 1) when the hand-held electric power tool is switched off. For this purpose, a programmed storage module 20 with a nonvolatile data memory 22 is provided in the computing means 2b (FIG. 1). After the switch-off time 19, other measurements of the cooling air temperature 6 (in this case, the cooling air that is stationary in the hand-held electric power tool, not the flowing cooling air) are carried out and stored by the storage module 20 in logarithmically increasing time intervals over a sufficiently long time period tA<t<t0 between the switch-off time tA 19 and the actual time t0.

According to FIG. 5, the motor temperature model 11 with the stored past motor temperatures 17 is initialized by the computing means 2b (FIG. 1) when first put into operation and when restarting after a switch-off period 19. For this purpose, a programmed initialization module 18 is provided in the computing means 2b (FIG. 1), and when this initialization module 18 is activated, the data memory 22 (FIG. 4) is read out and, based on a cooling function 24 depending on the switch-off time 19, the stored cooling air temperatures 6 and the past motor temperatures 17, the initial motor temperature 8′ is determined and outputted and is entered in the motor temperature model 11 (FIG. 3) as parameter.

Though the present invention was shown and described with references to the preferred embodiment, such is merely illustrative of the present invention and is not to be construed as a limitation thereof and various modifications of the present invention will be apparent to those skilled in the art. It is therefore not intended that the present invention be limited to the disclosed embodiment or details thereof, and the present invention includes all variations and/or alternative embodiments within the spirit and scope of the present invention as defined by the appended claims.

What is claimed is:

1. A hand-held electric power tool, comprising a hand-held outer housing (23); an electric motor (1) for driving the power tool; a fan (3) for generating a flow (4) of cooling air; an electronics module (2) including an electronic motor control (2a) and computing means (2b) for monitoring motor temperature and having a motor temperature model (11); and a temperature sensor (5) for sensing temperature (6) of the cooling air flow (4) and arranged directly at the electronics module (2) and connected therewith, the computing means (2b) controlling the motor temperature in accordance with data communicated by the sensor (5).

2. A hand-held electric power tool according to claim 1, wherein the temperature sensor (5) is arranged on an inflow side between the outer housing (23) and the electric motor (1).

3. A hand-held electric power tool according to claim 1, wherein the computing means (2b) contains a programmed algorithm (7) for monitoring the temperature of the electric motor (1) which, depending on a calculated actual motor temperature (8), interrupts motor current (9) of the electric motor (1) by an electronic switch (25) of the motor control (2a) when a calculated current limit value (10) is exceeded.

4. A hand-held electric power tool according to claim 1, wherein the motor temperature model (11) is based on actual measurements of motor current (9), motor voltage (12), the cooling air temperature (6) of the cooling air flow (4), and initial motor temperature (8′).

5. A hand-held electric power tool according to claim 1, wherein the motor temperature model (11) comprises a logical circuit of software modules.

6. A hand-held electric power tool according to claim 1, wherein the computing means (2b) has a programmed storage module (20) which is write-connected to a nonvolatile data memory (22).

7. A hand-held electric power tool according to claim 1, wherein the computing means (2b) is also connected to a power source (21) after the electric motor (1) is switched off.

8. A hand-held electric power tool according to claim 1, wherein a programmed initialization module (18) which is read-connected to a data memory (22) is provided in the computing means (2b).
